(19) United States
(12) Patent Application Publication
(10) Pub. No.: US 2017/0178866 A1
(43) Pub. Date: Jun. 22, 2017

(54) APPARATUS AND TECHNIQUES FOR TIME MODULATED EXTRACTION OF AN ION BEAM

(71) Applicant: Varian Semiconductor Equipment Associates, Inc., Gloucester, MA (US)

(72) Inventors: Svetlana B. Radovanov, Brookline, MA (US); Peter F. Kurunczi, Cambridge, MA (US); Alexandre Likhanskii, Malden, MA (US)

(21) Appl. No.: 14/977,714

(22) Filed: Dec. 22, 2015

(51) Int. Cl. H01J 37/32; C23C 14/48; H01J 37/147

(52) U.S. Cl. CPC H01J 37/32412; H01J 37/147; H01J 37/32715; C23C 14/48; H01J 2237/151; H01J 2237/3365; H01J 2237/327

(57) ABSTRACT

A plasma processing apparatus may include: a plasma chamber; a power source to generate a plasma in the plasma chamber; an extraction voltage supply coupled to the plasma chamber to apply a pulsed extraction voltage between the plasma chamber and a substrate; an extraction assembly disposed along a side of the plasma chamber between the plasma chamber and the substrate, the extraction assembly having at least one aperture, the at least one aperture defining a first ion beam when the plasma is present in the plasma chamber and the pulsed extraction voltage is applied; a deflection electrode adjacent the extraction assembly; and a controller to synchronize application of the pulsed extraction voltage with application of a pulsed deflection voltage to the deflection electrode.

### FIELD

The present embodiments relate to a plasma processing apparatus, and more particularly control of delivery of charged species to a substrate from a plasma.

### BACKGROUND

Known apparatuses used to treat substrates with ions include beamline ion implanter and compact plasma processing apparatus, such as plasma immersion ion implantation tools. These two different apparatuses are appropriate for implanting ions over a range of energies. In beamline ion implanters, ions are extracted from a source, mass analyzed, and then transported to the substrate surface. In a plasma immersion ion implantation apparatus, a substrate is located in the same chamber and the plasma is generated adjacent to the substrate. The substrate is set at negative potential with respect to the plasma and ions that cross the plasma sheath in front of the substrate impinge on the substrate at perpendicular incidence angle. In other compact apparatus, an extraction system may be placed adjacent a plasma chamber in order to extract ions that are provided to a substrate. Recently a new class of processing apparatus that allows control of the extracted ion angular distribution (IAD) of ions provided to a substrate has been developed. In this apparatus, ions are extracted from a plasma chamber, but unlike the a beamline ion implanter where the substrate is located remotely from the ion source, the substrate is located proximate the plasma chamber. Ions are extracted through an aperture or set of apertures having a particular geometry located in an extraction plate that is placed proximate a plasma. Changing the geometry of the aperture and electric field in the vicinity of the aperture allow control of the ion angular distribution, i.e., the mean angle and angular spread of the ions. This may be appropriate to treat planar substrates as well as substrates having 3D structures, i.e., substrates presenting surface features having sidewalls or other features extending above or below a plane of the substrate. In any of the aforementioned apparatus, in addition to ion implantation, ions may be provided to treat substrates including etching of a substrate, deposition of a layer, or other treatment.

In the various types of compact sources described above, ions may be directed to a substrate in a continuous manner or in a series of pulses. For example, a substrate may be grounded and a plasma chamber may be subject to positive DC voltage pulses to drive a series of positive ion beam pulses to the substrate. To provide charge neutralization at the substrate, it is useful to ensure that electrons are provided to the substrate. In compact plasma systems, such as pulsed DC voltage systems, components designed to extract ions and control delivery of ions to the substrate may not be ideally suited to controlling delivery of electrons to the substrate.

It is with respect to these and other considerations that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a plasma processing apparatus may include: a plasma processing apparatus comprising: a plasma chamber; a power source to generate a plasma in the plasma chamber; an extraction voltage supply coupled to the plasma chamber to apply a pulsed extraction voltage between the plasma chamber and a substrate; an extraction assembly disposed along a side of the plasma chamber between the plasma chamber and the substrate, the extraction assembly having at least one aperture, the at least one aperture defining a first ion beam when the plasma is present in the plasma chamber and the pulsed extraction voltage is applied; a deflection electrode adjacent the extraction assembly; and a controller to synchronize application of the pulsed extraction voltage with application of a pulsed deflection voltage to the deflection electrode.

In a further embodiment, a method of processing a substrate may include providing an extraction assembly along a side of a plasma chamber and a deflection electrode adjacent the extraction assembly; generating a plasma in the plasma chamber; and exposing the substrate to a treatment from the plasma, the treatment comprising: providing a pulsed ion beam to the substrate; and synchronizing the pulsed ion beam with application of a pulsed deflection voltage to the deflection electrode, wherein during the treatment the pulsed ion beam is directed to the substrate, and wherein a controlled dose of electrons is provided to the substrate.

In an additional embodiment, an extraction system may include: an extraction voltage supply coupled to a plasma chamber to apply a pulsed extraction voltage between the plasma chamber and a substrate, the pulsed extraction voltage comprising a voltage waveform comprising a series of extraction voltage pulse periods, an extraction voltage pulse period having a first ON portion and a first OFF portion; an extraction assembly disposed along a side of the plasma chamber, the extraction assembly including an extraction plate having at least one aperture, the at least one aperture defining a first ion beam when the plasma is present in the plasma chamber and the pulsed extracted voltage is applied between the plasma chamber and the substrate; a deflection electrode adjacent the extraction plate; a deflection voltage source coupled to the deflection electrode, the deflection voltage source to apply the deflection voltage to the deflection electrode as a deflection voltage waveform comprising a series of deflection voltage pulse periods, a deflection voltage pulse period having a second ON portion and a second OFF portion; and a controller including a synchronization component to synchronize the first OFF portion of the extraction voltage pulse periods with the second OFF portion of the deflection voltage pulse periods.

### BRIEF DESCRIPTION OF THE DRAWINGS

FIG. 1A depicts a side view of a plasma processing apparatus in block form according to embodiments of the disclosure;

FIG. 1B illustrates a bottom plan view of an embodiment of the extraction plate and deflection electrode of FIG. 1A;

FIG. 2A and FIG. 2B depict exemplary waveforms for time modulated extraction of an ion beam according to embodiments of the disclosure;

FIG. 2C and FIG. 2D show a scenario for generating a pulsed ion beam using an extraction voltage waveform;

FIG. 2E and FIG. 2F show a scenario for generating and controlling a pulsed ion beam by applying an extraction voltage waveform in conjunction with applying a deflection voltage waveform, according to embodiments of the disclosure;

FIG. 2G depicts exemplary waveforms for time modulated extraction of an ion beam according to other embodiments of the disclosure;

FIG. 3A, FIG. 3B, and FIG. 3C depict simulation results showing charge carrier behavior during an OFF portion of a pulsed extraction voltage waveform under one scenario according to with embodiments of the disclosure;

FIG. 3D, FIG. 3E, and FIG. 3F depict simulation results showing charge carrier behavior during an OFF portion of a pulsed extraction voltage waveform under a different scenario;

FIG. 4 there shows a graph illustrating the results of experimental measurements of deflector current collected at a deflection electrode;

FIG. 5 depicts an exemplary deflection electrode arrangement according to additional embodiments of the disclosure;

FIG. 6 depicts an exemplary process flow according to embodiments of the disclosure; and

FIG. 7 depicts another exemplary process flow according to embodiments of the disclosure.

### DETAILED DESCRIPTION

The present embodiments will now be described more fully hereinafter with reference to the accompanying drawings, in which some embodiments are shown. The subject matter of the present disclosure, may be embodied in many different forms and is not to be construed as limited to the embodiments set forth herein. These embodiments are provided so that this disclosure will be thorough and complete, and will fully convey the scope of the subject matter to those skilled in the art. In the drawings, like numbers refer to like elements throughout.

The embodiments described herein provide apparatus, systems, and methods for processing a substrate using ions. In particular embodiments, a novel extraction system and technique are provided to improve ion beam treatment of a substrate. The present embodiments may be employed in particular in plasma based systems where ions are extracted from plasma through an extraction system and delivered to a substrate.

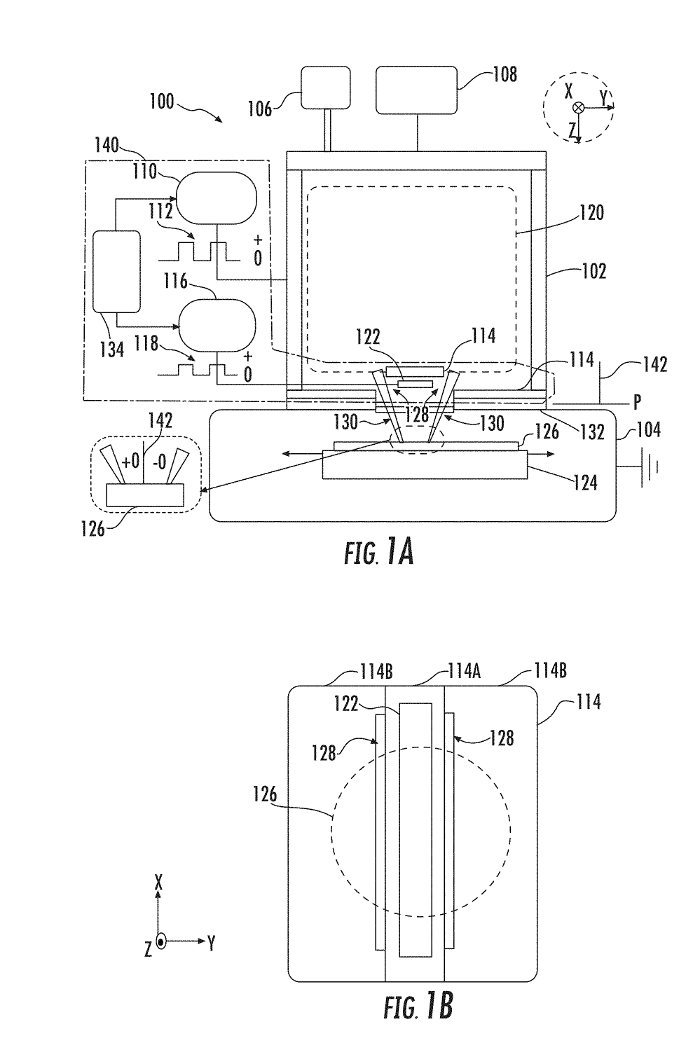

FIG. 1A depicts a side view of a plasma processing apparatus 100 in block form according to embodiments of the disclosure. The plasma processing apparatus 100 may be used to treat a substrate 126 with ions for the purpose of ion implantation, etching, surface modification, deposition, or other processing. The plasma processing apparatus 100 may include a process chamber 104 adjacent the plasma chamber 102, where the process chamber 104 houses a substrate stage 124. In various embodiments, the substrate stage 124 may be movable, such as in directions parallel to the Y-axis, X-axis, and Z-axis of the Cartesian coordinate system shown in FIG. 1A. The plasma processing apparatus 100 may further include at least one gas source to provide a gas for ionization and formation of plasma 120 in plasma chamber 102. The gas source(s) is illustrated for simplicity as gas source 108.

The plasma processing apparatus 100 may further include a power source, shown as a power supply 106, to send a power signal to the plasma chamber 102 to generate the plasma 120. In different embodiments, the power supply 105 and plasma chamber 102 may form part of an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, or other plasma sources known to those skilled in the art. In various embodiments, the power supply 106 may apply a continuous plasma power to the plasma chamber 102 or may generate a pulsed plasma power having a pulsed waveform.

As further shown in FIG. 1A, the plasma processing apparatus 100 may include various components that function as an extraction system 140 to extract ions, for example, in the form of ion beam(s), from the plasma chamber 102. In various embodiments, the extraction system 140 may include an extraction voltage supply coupled to the plasma chamber 102 to apply a pulsed extraction voltage between the plasma chamber and the substrate 126. In some embodiments, for example, the plasma chamber 102 may be grounded and an extraction voltage supply may apply a pulsed negative voltage to the process chamber 104 and substrate 126 to extract a pulsed positive ion beam from the plasma chamber 102. In the embodiments detailed below, the extraction system 140 may operate to apply a pulsed positive voltage to the plasma chamber 102 while the substrate 126 is grounded. In this manner, a pulsed positive ion beam may also be extracted from plasma chamber 102 and directed to the substrate 126. In either case, the pulsed positive ion beam may be synchronized with pulsed deflection voltages as detailed in the embodiments below.

In the example of FIG. 1A, the extraction system 140 may include an extraction assembly disposed along a side of the plasma chamber 102, where the extraction assembly includes at least one aperture. This aperture(s) may be used to define an ion beam(s) when the plasma 120 is present in the plasma chamber 120, as discussed below. In the embodiment shown in FIG. 1A, the extraction assembly is embodied as an extraction plate 114, where the extraction plate 114 includes extraction aperture(s), shown as extraction aperture(s) 128. The extraction system 140 may also include an extraction voltage supply 110 coupled to the plasma chamber 102. In various embodiments, the extraction voltage supply 110 may apply a DC voltage as a pulsed extraction voltage 112 to the plasma chamber 102. In some implementations, the pulsed extraction voltage 112 may generate a series of positive voltage pulses to the plasma chamber 102, raising the potential of the plasma chamber 102 above ground potential (0 volts). At the same time, the process chamber 104, as well as the substrate stage 124 and substrate 126 may be connected to ground potential. As further shown in FIG. 1A, the extraction plate 114 may be electrically coupled to the plasma chamber 102 and may therefore reside at the same voltage. The extraction plate 114 and plasma chamber 102 may be electrically isolated from the process chamber 104 by insulators 132. Accordingly, when a positive voltage is applied to the plasma chamber 102, the substrate 126 may become negatively biased with respect to plasma chamber 102 and plasma 120, causing positive ions in the form of ion beams 130 to be extracted from the plasma 120 and directed to the substrate 126. In the example of FIG. 1A, for purposes of illustration, a pair of extraction apertures are shown, where two different respective ion beams are generated. In other embodiments, an extraction plate 114 may include just one extraction aperture or a greater number of extraction apertures.

In particular, the pulsed extraction voltage 112 may be generated as a voltage waveform having a series of extraction voltage pulse periods, where an extraction voltage pulse period has an ON portion and an OFF portion. As in known pulsed plasma systems for processing a substrate, adjusting the duty cycle of such an extraction voltage waveform may provide control of substrate processing, such as the effective ion current delivered to a substrate over time. In various embodiments, the frequency of the extraction voltage waveform generating the pulsed extraction voltage 112 may range between several Hz to 100 kHz. In some examples, the frequency of the extraction voltage waveform may range from a few hundred kHz up to the MHz range.

In various embodiments, the magnitude of the voltage during ON portions, the ON voltage, may be between +50 V and +10,000 V. In other embodiments, the magnitude of the ON voltage may be greater than 10,000 V. The embodiments are not limited in this context.

As suggested in FIG. 1A, the plasma chamber 102 and extraction plate 144 may act as an angled ion source providing an angled ion beam. For example, the ion beams 130 may be extracted from the plasma 120 and directed to the substrate at a non-zero angle of incidence with respect to a perpendicular 142 to a plane P of the extraction plate 114, where the plane P may also lie parallel to a plane of substrate 126 (see X-Y plane shown in FIG. 1A, for example). Because of this extraction, the ion beams 130 may impinge upon the substrate 126 at a non-zero angle of incidence with respect to perpendicular 142, shown as the angle θ. For purpose of illustration, two different ion beams having the same ion energy are illustrated directed at different angles of incidence, where one ion beam may form a positive angle with respect to the perpendicular 142, shown as +θ, while the other ion beam may form a negative angle with respect to the perpendicular 142, shown as −θ. This non-zero incidence angle may be useful to control exposure of different surfaces or regions of the substrate 126, including instances where the substrate has features having surfaces extending at different angles with respect to the plane P. In general, the ion beams 130 may be characterized by an ion angular distribution (IAD). The term “ion angular distribution” refers to the mean angle of incidence of ions (see θ) in an ion beam with respect to a reference direction such a perpendicular to a substrate, as well as to the width of distribution or range of angles of incidence centered around the mean angle, termed “angular spread” for short.

In accordance with embodiments of the disclosure, the extraction system 140 may also include an additional component to control properties of an ion beam extracted from the plasma chamber 102. In particular, a deflection electrode 122 may be provided adjacent the extraction plate 114. The deflection electrode 122 may be independently coupled to a separate voltage supply to provide further control of the ion beams 130. In various embodiments disclosed herein, the deflection electrode 122 may be located with respect to the extraction plate 114 and extraction apertures 128 in a manner that facilitates modifying beam properties of the ion beams 130. For example, when a deflection voltage 118 is applied to the deflection electrode 122, the mean angle of incidence of ions or an angular spread of ions may be varied in the ion beams 130. In various embodiments, as suggested in FIG. 1A, an extraction assembly such as extraction plate 114, may be disposed between the plasma chamber 102 and the deflection electrode 122. As suggested in FIG. 1A, this arrangement serves to shield the deflection electrode 122 from ions extracted from the plasma 120, so the deflection electrode may alter the ion beams 130 by application of a deflection voltage, while not being impacted by the ion beams 130.

FIG. 1B illustrates a bottom plan view of an embodiment of the extraction plate 114 and deflection electrode 122 looking toward the plasma chamber 102. In this embodiment, the extraction apertures 128 are elongated apertures having a long direction along the X-axis, making the extraction apertures 128 suitable for extracting ribbon beams. A ribbon beam may have an elongated cross section where the ribbon beam extends a greater distance along the X-axis as opposed to along the Y-axis. In the embodiment of FIGS. 1B and 1A, a central portion 114A of the extraction plate 114 may extend above a plane of the outer portions 114B of the extraction plate. In other embodiments, the extraction plate 114 may have a planar configuration. Moreover, in further embodiments the extraction plate 114 may include just one extraction aperture 128 adjacent a given deflection electrode. While a given ion beam 130 may impact a narrow portion of the substrate 126, an entirety of the substrate 126 may be exposed to ions by scanning the substrate along the Y-direction, for example.

The present inventors have discovered techniques for improving substrate processing using an ion beam provided by an extraction system including a deflection electrode as generally shown in FIG. 1A. In particular, in accordance with various embodiments, the deflection voltage 118 may be provided as a pulsed DC voltage composed of a deflection voltage waveform having a series of deflection voltage pulse periods. This pulsed deflection voltage may improve treatment of a substrate by providing doses of electrons in intervals between pulses in addition to ions directed to the substrate during the pulses.

A given deflection voltage pulse period may be characterized by an ON portion and an OFF portion, as further discussed below. In various embodiments, the magnitude of voltage during ON portions of the deflection voltage pulse period, the ON voltage, may range between +50 V and +1000 V. The embodiments are not limited in this context.

By providing a pulsed deflection voltage to the deflection electrode 122, the properties of ion beams 130 may be adjusted, while at the same time charge neutralization at the substrate 126 is enhanced. This charge neutralization may be especially useful for charge-free ion implantation or other charge-free material modification of insulators, as well as conductors.

As shown in FIG. 1A, the plasma processing apparatus 100 may include a controller 134 coupled to the extraction voltage supply 110 and to the deflection voltage source 116. The controller 134 may synchronize application of the pulsed extraction voltage 112 to the plasma chamber 102 with application of a pulsed deflection voltage 118 to the deflection electrode 122. As detailed below, the provision of synchronized signals to the respective components of plasma processing apparatus 100 may afford enhanced charge neutralization at the substrate 126 during ion beam processing while also affording further control of ion beams 130.

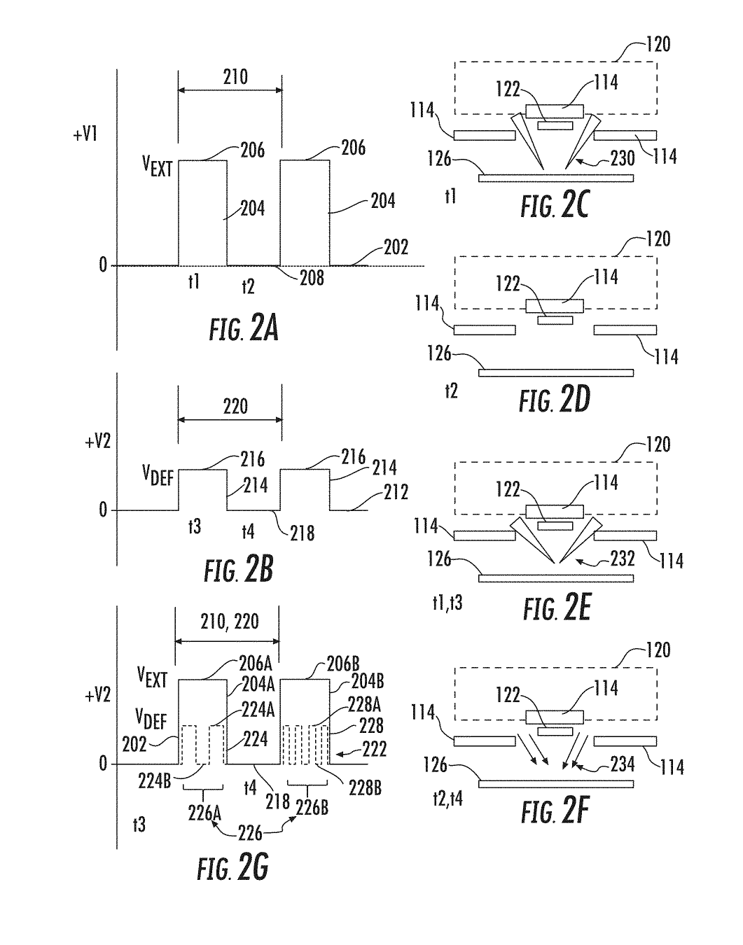

FIG. 2A and FIG. 2B depict exemplary waveforms for time modulated extraction of an ion beam according to embodiments of the disclosure. According to some embodiments, the range of the pulsed frequency may vary from few kHz to several MHz. In various embodiments, the waveforms of FIG. 2A and FIG. 2B may be applied to an extraction assembly and deflection electrode, respectively. Turning first to FIG. 2A, there is shown an extraction voltage waveform 202, where the extraction voltage waveform 202 is provided as a series of voltage pulses 204. An extraction voltage pulse period 210 includes an ON portion 206 where voltage is at a target value and is generally maintained at the target value, and an OFF portion 208, where voltage is zero. Turning now to FIG. 2C and FIG. 2D, there is shown a scenario for generating a pulsed ion beam using the extraction voltage waveform 202 while not necessarily applying a pulsed deflection voltage to the deflection electrode 122. As an example, a pulsed extraction voltage of 1500 V may be applied to generate ion beams having 1500 eV ions, while a continuous deflection voltage of 500 V is applied to the deflection electrode 122 to further control ion angular distribution of the ion beams. As shown in the scenario of FIG. 2C, during the ON portion 206, represented by time t1, ions are extracted as the ion beams 230 from a plasma. The ions are extracted at a voltage approximately equal to the voltage in the ON portion 206, referred to herein simply as the extraction voltage or VEXT. The duty cycle of the extraction voltage waveform 202 may be characterized as the duration of the ON period T_{ON} to duration of extraction voltage pulse period, T_{PER}, so the duty cycle=T_{ON}/T_{PER}. The average ion current delivered over time at a target extraction voltage may therefore be controlled by adjusting the duty cycle. As shown in the scenario of FIG. 2D, during the OFF portion 208, represented by time t2, the ion beams 230 are absent because the extraction plate 114 is set at zero volts, the same as the voltage of substrate 126. In other embodiments, this procedure may also work well at rf frequencies. For example, the period of the extraction voltage and deflection voltage waveforms may be much shorter, on the order of ˜100 ns. In principle, a pulse period may be adjusted to achieve electron temperature and ion density steady state and maintain ionization rate at a desired level. The pulse frequency and the duty cycle may be carefully chosen to realize a specific process requirement.

Turning now to FIG. 2B, there is shown a deflection voltage waveform 212, where the deflection voltage waveform 212 is provided as a series of deflection voltage pulses 214. A deflection voltage pulse period 220 includes an ON portion 216 where voltage is at a target deflection voltage value and generally maintained at the target deflection voltage value, and an OFF portion where voltage is zero. During the ON portion 216, represented by time t3, a deflection voltage established at the deflection electrode 122 may generate an electric field having a field strength determined at least in part by the magnitude of the deflection voltage and the magnitude of electric fields generated by the extraction plate 114, for example.

Turning now to FIG. 2E and FIG. 2F, there is shown a scenario for generating and controlling a pulsed ion beam by applying the extraction voltage waveform 202 to the extraction plate 114 in conjunction with applying the deflection voltage waveform 212 to the deflection electrode 122. In the scenario of FIG. 2E, the instance is labeled as t1,t3 meaning that the scenario corresponds to an instance where t1 and t3 coincide. In other words, the ON portion 216 of deflection voltage waveform 212 coincides with the ON portion 206 of extraction voltage waveform 202. In this scenario, the ion beams 232 are extracted from the plasma 120 while being modified by the deflection voltage VDEF present on the deflection electrode 122. For example, the angle of incidence θ of the ion beams 232 may be greater than for ion beams 230 in the scenario of FIG. 2B, where no deflection voltage is applied. In the scenario of FIG. 2F, the instance is labeled as t2,t4 meaning that the scenario corresponds to an instance where t2 and t4 coincide. In other words, the OFF portion 218 of deflection voltage waveform 212 coincides with the OFF portion 208 of extraction voltage waveform 202. As shown in the scenario of FIG. 2F, the ion beams 232 are absent because the extraction plate 114 is set at zero volts, the same as the voltage of substrate 126. Moreover, because the deflection electrode is also set at zero voltage at this instance, electrons 234 (or negative ions) streaming out of the plasma 120 are not attracted to the deflection electrode 122, and may accordingly impinge upon the substrate 126 as shown. In this scenario, the electrons 234 (or negative ions generated in the plasma) may neutralize positive charge built up on the substrate 126 occurring during ON portion 206 of the extraction voltage waveform 202 when the ion beams 232, carrying positive charge, strike the substrate.

In view of the above results, various embodiments provide improved substrate processing by synchronizing pulsed extraction voltage for generating ion beams with pulsed deflection voltage applied to a deflection electrode. Turning again to FIG. 2A and FIG. 2B, in some embodiments, the extraction voltage pulse period 210 (or frequency) may be set the same as the deflection voltage pulse period 220 (or frequency). Moreover, the extraction voltage pulse period 210 may be synchronized to the deflection voltage pulse period 220 by setting the ON portions of the respective waveforms to start at the same instance in time. In this manner, the OFF portion 208 of extraction voltage waveform 202 may be synchronized with the OFF portion 218 of the deflection voltage waveform 212. Accordingly, in any given time when an ion beam is switched “OFF” by the extraction voltage waveform 202, the deflection voltage at the deflection electrode 122 is also “OFF”, that is, no voltage is applied to the deflection electrode. Because the deflection electrode 122 does not have a positive potential, this allows electrons to stream to the substrate, since the electrons are not accelerated to the deflection electrode.

This generating of pulsed voltage to the deflection electrode 122 synchronized with the pulsed extraction voltage provides the ability to operate a pulsed ion beam apparatus over a wider range of conditions compared with known apparatus. For example, known pulsed ion beam systems may employ diode, triode or tetrode configurations where bias is applied to an extraction electrode and additional electrode(s) are separately biased. In the known systems, operation of pulsed ion beams may be limited to a certain range of parameters because of limited flux of electrons to a substrate thus causing charge damage on the substrate. For example, plasma power, duty cycle or frequency of a pulse waveform may be limited to provide longer OFF portions to allow at least some electrons to reach the substrate during the OFF portions. In the present embodiments, due to synchronization of extraction voltage waveforms and deflection voltage waveforms, a processing apparatus may be operated at relatively higher power, such as a plasma power of 2 kW or higher, relatively higher frequency, such as a frequency of 10 kHz or more, and relatively higher duty cycle, such as 50% or greater. At pulsed frequencies of 100 kHz and above a higher duty cycle of approximately 90% may be used if adequate electron flux is delivered to the substrate. Accordingly, the present embodiment enables high throughput and no charge build up at a substrate, by using high duty cycles because adequate electron flux may be directed to the substrate during OFF portions.

Notably, in further embodiments, pulsed deflection voltage applied to a deflection electrode may be synchronized with pulsed plasma power as opposed to synchronizing with pulsed extraction voltage. As an example, in some embodiments, a constant voltage may be applied between a plasma chamber and substrate while a plasma power supply generates a pulsed power waveform having similar shape to the extraction voltage waveform 202. The pulsed power waveform may be synchronized with the deflection voltage waveform 212, resulting in a pulsed plasma generating a pulsed ion beam is provided in synchronization with ON portions 216 of the deflection voltage waveform 212. Similarly, the pulsed plasma may be OFF during OFF portions 218.

In other embodiments, pulsing of a deflection electrode may take place during an ON portion of an extraction voltage waveform. For example, in some circumstances it may be useful to adjust a beam angle or angular spread of an ion beam during ion beam processing. During an ON portion of an extraction voltage waveform, when an ion beam is directed to the substrate 126, application of voltage to the deflection electrode 122 may alter such beam properties, as opposed to when no deflection voltage is present, as discussed. While the scenario of a constant deflection voltage applied to a deflection electrode 122 as in FIG. 2B may generate a constant beam property during an ON portion 206, the beam properties may be dynamically varied by pulsing the deflection electrode 122 during the ON portion 206.

Turning now to FIG. 2G there is shown a scenario for pulsing a deflection electrode during the ON portion 206 to dynamically adjust beam properties, while still providing neutralization during OFF portion 208. As illustrated, the extraction voltage waveform 202 is shown having an extraction voltage pulse period 210, described above. There are shown two extraction voltage pulses, a first extraction voltage pulse 204A, and second extraction voltage pulse 204B, where the two pulses may generally be equivalent to one another. Accordingly, a pulsed ion beam having the same duty cycle and period may generally be provided using the extraction voltage waveform 202. In addition, a deflection voltage waveform 222 is shown in dashed line for clarity. The deflection voltage waveform 222 may be generally synchronized with the extraction voltage waveform, where the deflection voltage waveform 222 has the same period, deflection voltage pulse period 220, as the extraction voltage pulse period 210. The two pulse periods may also begin at the same time. In this manner, the deflection voltage may be zero during OFF portions 208 so negative charge may stream to the substrate as described above. Additionally, the deflection voltage waveform 222 may be characterized by a plurality of ON portions 226, where an ON portion 226 includes at least one deflection voltage pulse, where the duration of the deflection voltage pulse may be different that the duration of the ON portion 206. As illustrated in FIG. 2G in particular, an ON portion 226A has a plurality of deflection voltage pulses 224, synchronized to take place during ON portion 206A of first extraction voltage pulse 204A. Between a given deflection voltage pulse and a following deflection voltage pulse during ON portion 206A, the deflection voltage may be zero. Accordingly, an ion beam extracted during ON portion 206A may experience a pulsed deflection field, causing the properties of the ion beam, such as beam angle or angular spread, to alter in response to the pulses. For example, during ON sub-portion 224A, the angle of an ion beam with respect to perpendicular 142 may have a first value, while the angle has a second value during OFF sub-portion 224B. Thus, the angle of such an ion beam may dynamically vary during processing over ON portion 206A.

As further shown in FIG. 2G, the deflection voltage waveform 222 includes an ON portion 226B having a plurality of deflection voltage pulses 228, synchronized to take place during ON portion 206B of second extraction voltage pulse 204B. Between a given deflection voltage pulse and a following deflection voltage pulse during ON portion 206B, the deflection voltage may also be zero. Accordingly, an ion beam extracted during ON portion 206B may experience a pulsed deflection field, causing the properties of the ion beam, such as beam angle or angular spread, to alter in response to the pulses. In this example, the ON sub-portion 228A of deflection voltage pulses 228, as well as OFF sub-portion 228B, may be shorter than for deflection voltage pulses 224. In this manner, the properties of an ion beam extracted during the ON portion 206B may fluctuate more rapidly. In general, in accordance with the present embodiments, a deflection voltage waveform may be provided where OFF portions are synchronized with OFF portions of a pulsed ion beam, and where a pattern of deflection voltage pulses takes place during an ON portion of the pulsed ion beam. The deflection voltage pulses may have any duration less than or equal to the duration of the ON portion of the pulsed ion beam, and may be provided in any number, and any interval between pulses within a given ON portion, where the pattern of deflection voltage pulses may vary between different ON portions, as appropriate for a given treatment.

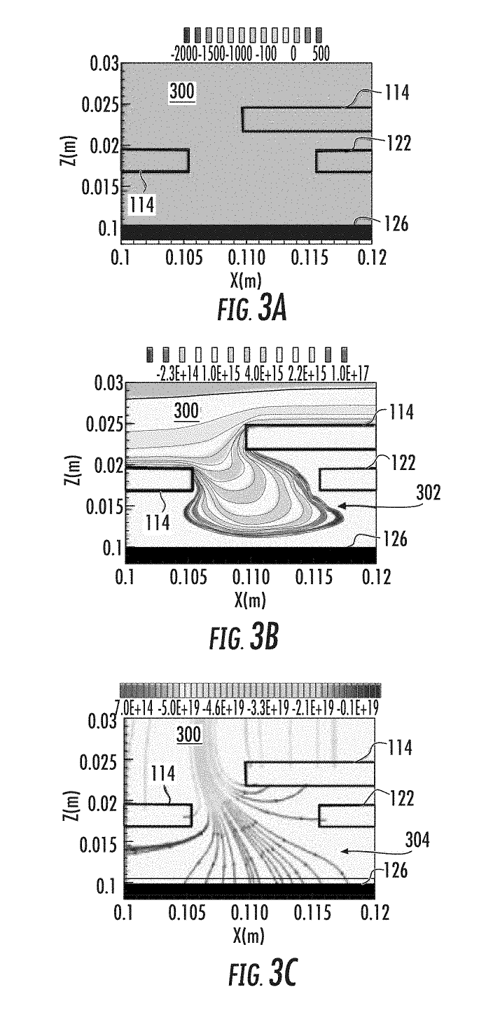

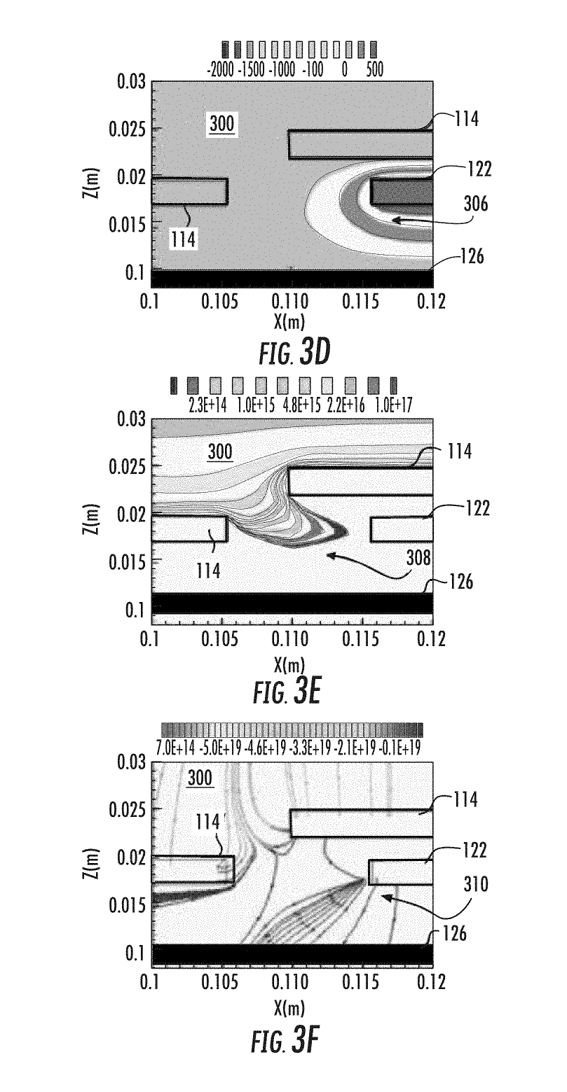

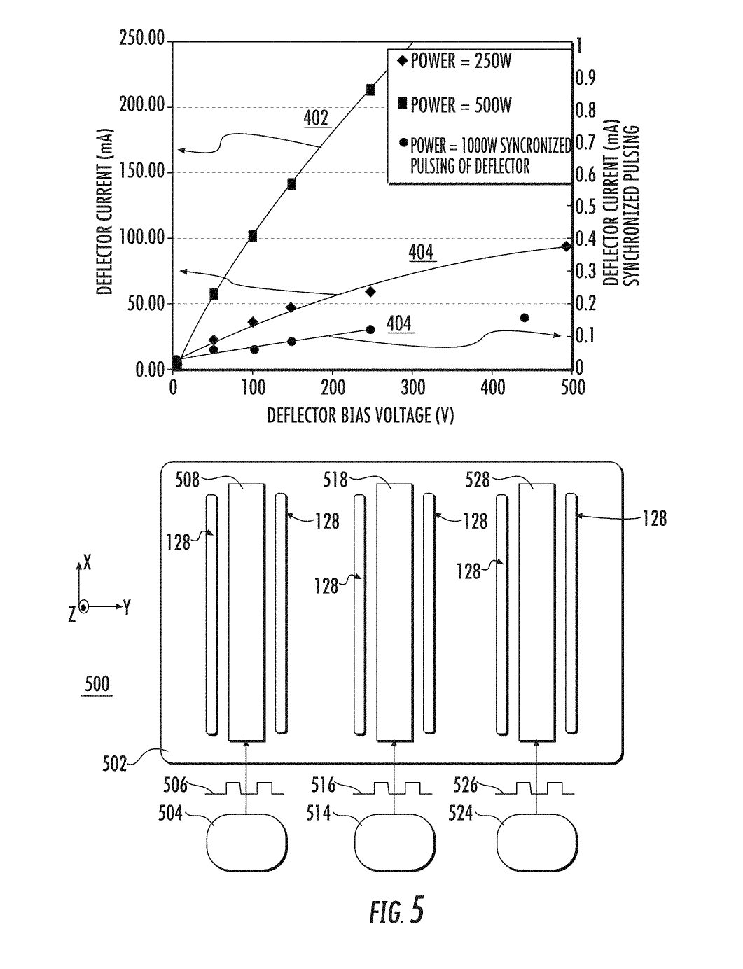

FIG. 3A, FIG. 3B, and FIG. 3C depict simulation results showing charge carrier behavior during an OFF portion of a pulsed extraction voltage waveform under one scenario according to embodiments of the disclosure. In the scenario of FIG. 3A, an electrical field map is shown, indicating uniform electrical field around the extraction plate 114, deflection electrode 122, and substrate 126. In particular, the scenario represents the case when an OFF portion of a pulsed deflection voltage waveform coincides with the OFF period of the pulsed extraction voltage waveform, as in FIG. 2F, wherein the extraction plate 114, deflection electrode 122, and substrate 126 may be at ground potential. Accordingly, because the substrate 126, deflection electrode 122 and extraction plate 114 are all at 0 V potential, no electric fields are present.

Turning now to FIG. 3B, there is shown a simulation of electron density at the instance shown in FIG. 3A. In this case, electrons 302 stream out of the plasma region 300 and may impact the substrate 126. As further shown in FIG. 3C, a small amount of low energy ions 304 may also leak out of the plasma region 300.

FIG. 3D, FIG. 3E, and FIG. 3F depict simulation results showing charge carrier behavior during an OFF portion of a pulsed extraction voltage waveform under a different scenario. In this scenario, the extraction plate 114 and substrate 126 may be at ground potential while a deflection voltage of 500 V is present at deflection electrode 122, generating an electric field 306 as shown in FIG. 3D, especially concentrated near the deflection electrode 122. This scenario may obtain when continuous deflection voltage is applied to the deflection electrode 122, or when an ON portion of a pulsed deflection voltage waveform occurs during the OFF portion of the pulsed extraction electrode.

As shown in FIG. 3E, illustrating electron density distribution at the same instance as shown in FIG. 3D, electrons 308 are attracted to the deflection electrode 122 and do not impinge upon the substrate 126. As further shown in FIG. 3F where ion flux distribution is shown, a small amount of lower energy ions, shown as ions 310, may impact the substrate at this time. Accordingly, the results of FIGS. 3D-3F suggest electron current to a substrate may be reduced or eliminated during an OFF period of a pulsed extraction voltage waveform when positive dc voltage is maintained on a deflection electrode.

Turning now to FIG. 4 there is shown a graph illustrating the results of experimental measurements of deflector current collected at a deflection electrode. The graph presents deflector current as a function of deflection voltage applied to a deflection electrode. In particular, the results are measured in a plasma apparatus where RF power is used to generate plasma, and ion beam energy is set at 1.5 keV. A pulsed signal is applied at 10 kHz with a duty cycle of 50%. In addition, a substrate is maintained at 0 V while a positive deflection voltage is applied to the deflection electrode. Curve 402 illustrates deflection current when plasma power is set at 500 W and a continuous deflection voltage is applied to the deflection electrode. As shown, deflection current rises steadily with deflection voltage and reaching approximately 220 mA at 250 V deflection voltage. Curve 404 illustrates deflection current when plasma power is set at 250 W and a continuous deflection voltage is applied to the deflection electrode. As shown, deflection current rises steadily with deflection voltage and reaches approximately 70 mA at 250 V deflection voltage. Accordingly, when a continuous deflection voltage is maintained on a deflection electrode, a relatively large negative current is collected at the deflection electrode. Turning to curve 406, this curve illustrates deflection current when plasma power is 1000 W and the deflection electrode is synchronously pulsed with the 10 kHz signal. In this set of experimental data, the deflection current is much lower than for curve 402 and curve 404. At 250 V applied to the deflection electrode, just 0.1 mA of deflection current is collected at the deflection electrode. Accordingly, the deflection current is reduced by 3 orders of magnitude or more with respect to the cases where a continuous deflection voltage is applied. This implies that a vast majority of electrons streaming out of plasma during an OFF period of an extraction pulse are not collected by the deflection electrode. Moreover, if a deflection voltage is negative with respect to the extraction voltage then an ion beam is accelerated towards the deflection electrode, where significant losses in the beam current delivered to a substrate are being observed.

While the aforementioned embodiments detail synchronization of pulsed deflection voltage applied to just one deflection electrode together with pulsed extraction voltage applied to one extraction plate having extraction apertures, other embodiments extend to triode, tetrode, or other multielectrode systems. For example, known plasma apparatus used to generate ion beams may employ extraction optics where triode, tetrode, pentode, configurations are used. In these configurations, intermediate electrodes may be placed in between an extraction aperture of an extraction plate and the substrate for the purpose of any combination of focusing, deflecting, accelerating and decelerating an ion beam. In additional embodiments of this disclosure, the potential (voltage) applied to at least one of these intermediate electrodes may be synchronously time modulated with an extraction voltage waveform, with the effect of allowing species including plasma electrons and negative ions to reach a substrate, while also modulating the trajectory (angles) of the extracted ion beam to meet a particular substrate process requirement.

Moreover, in additional embodiments, a plasma processing apparatus may include a first extraction aperture and at least one additional extraction aperture, where a respective additional deflection electrode is adjacent the at least one additional extraction aperture. For example, an extraction plate may have an array of apertures, where a first deflection electrode is disposed adjacent a first extraction aperture, or pair of apertures, and where a second deflection electrode is disposed adjacent a second extraction aperture, or pair of apertures. In addition, such a plasma processing apparatus may include a respective additional deflection voltage source, such as a second deflection voltage source coupled to the second deflection electrode, independently of a first deflection voltage source coupled to the first deflection electrode. The embodiments are not limited in this context. FIG. 5 depicts an exemplary deflection arrangement 500 according to additional embodiments of the disclosure. In this embodiment, an extraction plate 502 includes three pairs of apertures, shown as the extraction apertures 128, where a given deflection electrode is disposed adjacent and between a pair of apertures, similarly to the arrangement of FIG. 1B. A first deflection voltage supply 504 is provided, and may apply a first deflection voltage waveform 506 to a first deflection electrode 508. A second deflection voltage supply 514 is provided, and may apply independently a second deflection voltage waveform 516 to a second deflection electrode 518. A third deflection voltage supply 524 is provided, and may independently apply a third deflection voltage waveform 526 to a third deflection electrode 528. Moreover, in some embodiments, different voltage amplitudes may be employed to make appropriate angle corrections for a given pulsed ion beamlet, while in other embodiments the same deflection voltage waveform may be applied to the three deflection electrodes.

Moreover, in additional embodiments, an extraction assembly may be configured as an extraction grid rather than an extraction plate. A deflection electrode may also be configured as a deflection grid, and may function to deflect extracted ions during an ON portion of an extraction voltage waveform, while not collecting electrons during an OFF portion.

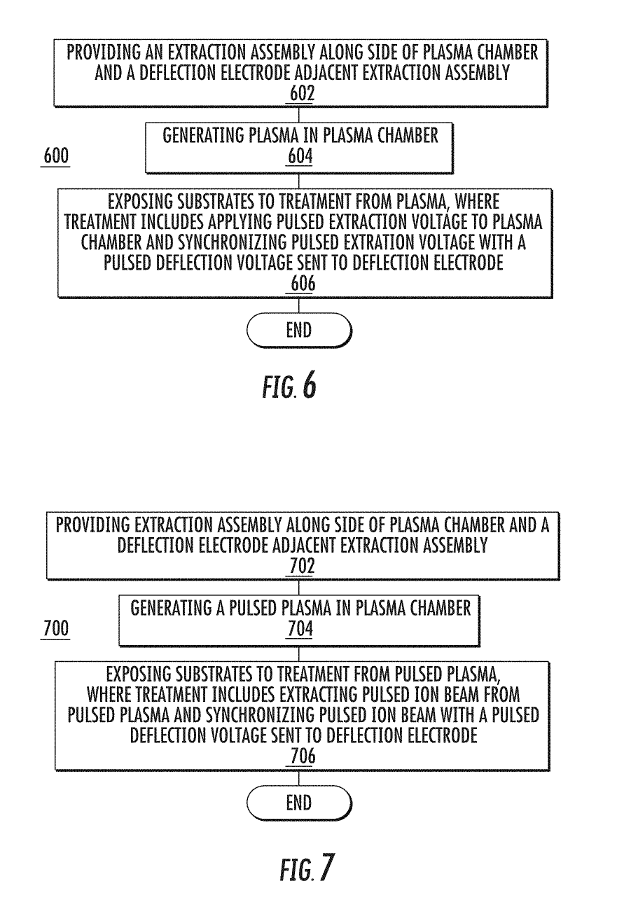

FIG. 6 depicts an exemplary process flow 600 according to embodiments of the disclosure. At block 602, the operation is performed of providing an extraction assembly along a side of a plasma chamber and a deflection electrode adjacent the extraction assembly. The extraction assembly may include an extraction plate or an extraction grid in different embodiments. At block 604, plasma may be generated in the plasma chamber. At block 606, the substrates may be exposed to a treatment from the plasma, where the treatment includes applying a pulsed extraction voltage to the plasma chamber and synchronizing the pulsed extraction voltage with a pulsed deflection voltage sent to the deflection electrode. During a given treatment, a pulsed ion beam may accordingly be directed to the substrate, while a dose of electrons is provided to the substrate. In various embodiments, due to synchronization of extraction voltage pulses with deflection voltage pulses, the pulsed ion beam may be directed to the substrate in alternating fashion with pulses of electrons or other negative charge carriers. In alternative embodiments, the pulsed deflection voltage may be synchronized with a pulsed plasma, where the pulsed plasma creates the pulsed ion beam in conjunction with a fixed extraction voltage, as opposed to using a pulsed extraction voltage to generate the pulsed ion beam.

FIG. 7 depicts another exemplary process flow 700, according to other embodiments of the disclosure. At block 702, the operation is performed of providing an extraction assembly along a side of a plasma chamber and a deflection electrode adjacent the extraction assembly. The extraction assembly may include an extraction plate or an extraction grid in different embodiments. At block 704, pulsed plasma may be generated in the plasma chamber. At block 706, the substrates may be exposed to a treatment from the pulsed plasma, where the treatment includes extracting a pulsed ion beam from the pulsed plasma and synchronizing pulsed ion beam with a pulsed deflection voltage sent to deflection electrode.

One advantage of the present embodiments is the ability to provide extra control to a pulsed ion beam by use of a deflection electrode while also providing negative charge to the substrate. Another advantage is the ability to perform charge-free processing of a substrate in pulsed ion systems having multiple electrodes, including diode, triode, or tetrode systems, for example. In such cases, all electrodes may be synchronously pulsed with an extraction voltage waveform.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, while the present disclosure has been described herein in the context of a particular implementation in a particular environment for a particular purpose, those of ordinary skill in the art will recognize the usefulness of the present embodiments is not limited thereto and the present embodiments may be beneficially implemented in any number of environments for any number of purposes. Thus, the claims set forth below are to be construed in view of the full breadth and spirit of the present disclosure as described herein.

What is claimed is:

1. A plasma processing apparatus comprising:
a plasma chamber;
a power source to generate a plasma in the plasma chamber;
an extraction voltage supply coupled to the plasma chamber to apply a pulsed extraction voltage between the plasma chamber and a substrate;
an extraction assembly disposed along a side of the plasma chamber between the plasma chamber and the substrate, the extraction assembly having at least one aperture, the at least one aperture defining a first ion beam when the plasma is present in the plasma chamber and the pulsed extraction voltage is applied;
a deflection electrode adjacent the extraction assembly; and
a controller to synchronize application of the pulsed extraction voltage with application of a pulsed deflection voltage to the deflection electrode.

2. The plasma processing apparatus of claim 1, the extraction assembly being disposed between the plasma chamber and deflection electrode.

3. The plasma processing apparatus of claim 1, the pulsed extraction voltage comprising an extraction voltage waveform comprising a series of extraction voltage pulse periods, an extraction voltage pulse period having a first ON portion and a first OFF portion, the plasma processing apparatus further comprising:
a deflection voltage source coupled to the deflection electrode, the deflection voltage source to apply the deflection voltage to the deflection electrode as a deflection voltage waveform comprising a series of deflection voltage pulse periods, a deflection voltage pulse period having a second ON portion and a second OFF portion, wherein the controller includes a synchronization component to synchronize the first OFF portion of the extraction voltage pulse periods with the second OFF portion of the deflection voltage pulse periods.

4. The plasma processing apparatus of claim 1, wherein the pulsed extraction voltage comprises an ON voltage between +250 V and +10000 V, and wherein the pulsed deflection voltage comprises an ON voltage between +50 V and +1000 V.

5. The plasma processing apparatus of claim 1, wherein the extraction assembly comprises an extraction plate, wherein the plasma chamber and extraction plate comprise an angled ion source, and wherein ions exit the extraction plate at a non-zero angle of incidence with respect to a perpendicular to a plane of the extraction plate.

6. The plasma processing apparatus of claim 5, wherein the extraction plate comprises a first extraction aperture and at least one additional extraction aperture, and wherein the deflection electrode is a first deflection electrode disposed adjacent the first extraction aperture, the plasma processing apparatus further comprising a respective additional deflection electrode disposed adjacent the at least one additional extraction aperture.

7. The plasma processing apparatus of claim 6, wherein the pulsed deflection voltage is supplied by a first deflection voltage source, the plasma processing apparatus further comprising a respective additional deflection voltage source coupled to the respective additional deflection electrode, independently of the first deflection voltage source.

8. The plasma processing apparatus of claim 1, wherein the extraction assembly comprises an extraction grid, wherein the deflection electrode comprises a deflection grid, and wherein the deflection grid defines an offset with respect to the extraction grid to produce an angled ion beam, wherein ions exit the deflection grid at a non-zero angle of incidence with respect to a perpendicular to a plane of the deflection grid.

9. A method of processing a substrate, comprising:
providing an extraction assembly along a side of a plasma chamber and a deflection electrode adjacent the extraction assembly;
generating a plasma in the plasma chamber; and
exposing the substrate to a treatment from the plasma, the treatment comprising:
providing a pulsed ion beam to the substrate; and
synchronizing the pulsed ion beam with application of a pulsed deflection voltage to the deflection electrode, wherein during the treatment the pulsed ion beam is directed to the substrate, and wherein a controlled dose of electrons is provided to the substrate.

10. The method of claim 9, comprising:
arranging the extraction assembly between the plasma chamber and the deflection electrode;
applying a pulsed extraction voltage between the plasma chamber and the substrate; and
synchronizing application of the pulsed extraction voltage with application of the pulsed deflection voltage to the deflection electrode.

11. The method of claim 10, wherein the pulsed extraction voltage is provided as a voltage waveform comprising a series of extraction voltage pulse periods, an extraction voltage pulse period having a first ON portion and a first OFF portion, the method further comprising:
applying the pulsed deflection voltage to the deflection electrode as a deflection voltage waveform comprising a series of deflection voltage pulse periods, a deflection voltage pulse period having a second ON portion and a second OFF portion, wherein the second ON portion comprises at least one deflection voltage pulse;
synchronizing the first OFF portion of the extraction voltage pulse periods with the second OFF portion of the deflection voltage pulse periods; and
synchronizing the first ON portion of the extraction voltage pulse periods with the second ON portion of the deflection voltage pulse periods.

12. The method of claim 11, wherein the pulsed deflection voltage directs the pulsed ion beam to the substrate at a first angle of incidence with respect to the substrate, and wherein when no deflection voltage is applied to the deflection electrode during application of the pulsed extraction voltage, the pulsed ion beam is generated having a second angle of incidence with respect to the substrate, different from the first angle of incidence.

13. The method of claim 9, further comprising changing a magnitude of the pulsed deflection voltage, wherein an angular spread of the pulsed ion beam is adjusted.

14. The method of claim 9 further comprising changing a frequency or a duty cycle of the pulsed deflection voltage to adjust beam properties of the pulsed ion beam.

15. The method of claim 11, wherein the pulsed extraction voltage comprises an ON voltage during the first ON portion having a magnitude between +250 V and +10000 V, and wherein the pulsed deflection voltage comprises an ON voltage during the second ON portion having a magnitude between +50 V and +1000 V.

16. The method of claim 11, wherein the extraction assembly comprises an extraction plate having a first extraction aperture and at least one additional extraction aperture, and wherein the deflection electrode is a first deflection electrode disposed adjacent the first extraction aperture, wherein the pulsed deflection voltage is a first pulsed deflection voltage, the method further comprising:
applying a second pulsed deflection voltage to a second deflection electrode disposed adjacent the at least one additional extraction aperture, wherein the second pulsed deflection voltage comprises a second deflection voltage waveform comprising a second series of deflection voltage pulse periods, a second deflection voltage pulse period having a third ON portion and a third OFF portion; and
synchronizing the first OFF portion of the extraction voltage pulse periods with the third OFF portion of the second deflection voltage pulse periods, wherein during a given extraction voltage pulse period, a first dose of electrons is provided through the first extraction aperture and a second dose of electrons is provided through the at least one additional extraction aperture.

17. The method of claim 10, wherein the plasma comprises a plasma power of 2 kW or greater, wherein the pulsed extraction voltage comprises a frequency of 10 kHz or more, and wherein the pulsed extraction voltage comprises a duty cycle of 50% or greater.

18. The method of claim 9, comprising:
generating the plasma as a pulsed plasma; and
synchronizing the pulsed plasma with application of the pulsed deflection voltage to the deflection electrode.

19. An extraction system, comprising:
an extraction voltage supply coupled to a plasma chamber to apply a pulsed extraction voltage between the plasma chamber and a substrate, the pulsed extraction voltage comprising a voltage waveform comprising a series of extraction voltage pulse periods, an extraction voltage pulse period having a first ON portion and a first OFF portion;
an extraction assembly disposed along a side of the plasma chamber, the extraction assembly including an extraction plate having at least one aperture, the at least one aperture defining a first ion beam when the plasma is present in the plasma chamber and the pulsed extracted voltage is applied between the plasma chamber and the substrate;
a deflection electrode adjacent the extraction plate;
a deflection voltage source coupled to the deflection electrode, the deflection voltage source to apply the deflection voltage to the deflection electrode as a deflection voltage waveform comprising a series of deflection voltage pulse periods, a deflection voltage pulse period having a second ON portion and a second OFF portion; and
a controller including a synchronization component to synchronize the first OFF portion of the extraction voltage pulse periods with the second OFF portion of the deflection voltage pulse periods.

20. The extraction system of claim 19, wherein the substrate is grounded and the voltage waveform is applied as a positive voltage to the plasma chamber, or the plasma chamber is grounded and the voltage waveform is applied as a negative voltage to the substrate.
